(19) United States
(12) Patent Application Publication
(10) Pub. No.: US 2013/0148319 A1
(43) Pub. Date: Jun. 13, 2013

(54) PRINTED CIRCUIT BOARD WITH EMI REMOVAL

(71) Applicant: LEI LI, Shenzhen City (CN)

(72) Inventor: LEI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/572,764

(22) Filed: Aug. 13, 2012

(30) Foreign Application Priority Data
Dec. 9, 2011 (CN) 201110408567.9

(51) Int. Cl. H05K 1/11; H05K 5/00

(52) U.S. Cl. 361/759; 174/262

(57) ABSTRACT

An exemplary printed circuit board includes a main body and a fixing component. The main body includes a first signal layer, a grounding layer, a power layer, and a second signal layer, arranged in that order. A through hole is defined on the main body, and includes a latching hole and a connecting hole. The latching hole is defined by and extends through the first signal layer. The connecting hole is defined by and extends from the second signal layer to the grounding layer, and communicates with the latching hole. The fixing component passes through the through hole, and thereby forms a direct connection with a grounding point of an electronic device.

### BACKGROUND

1. Technical Field

The disclosure generally relates to printed circuit boards (PCBs), and particularly to a PCB that can reduce electromagnetic interference.

2. Description of the Related Art

PCBs are used in electronic devices. When a PCB is used, electronic components of the PCB can interfere with each other, thereby suffering an interfering current called electromagnetic interference (EMI).

To prevent EMI, the interfering current needs to be passed to ground. Referring to FIG. 3, a PCB 100 includes first to fourth layers 11, 12, 13, and 14. A through hole 15 is defined on the PCB 100, and extends from a top layer (i.e., the first layer 11) to a bottom layer (i.e., the fourth layer 14) of the PCB 100. The PCB 100 also includes a conductive component 16, such as a copper surround on a periphery of the through hole 15. Thus, when a fixing component 17, such as a bolt is passed through the through hole 15, the head portion of the fixing component 17 abuts the conductive component 16, then a body portion of the fixing component 17 engages with a housing that is electrically connected to ground, and thereby the interfering current of the PCB 100 is electrically connected to ground. However, a grounding resistance of the fixing component 17 is generally high, and the conductive component 16 is easily oxidated due to exposure on the surface of the PCB 100, which will lead to an unreliability in the interfering current being connected to ground, and thereby the electromagnetic interference of the PCB 100 may not be fully canceled.

Therefore, there is room for improvement within the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views. Wherever possible, the same reference numbers are used throughout the drawings to refer to the same or like elements of an embodiment.

FIG. 1 is a schematic view of a printed circuit board, according to an exemplary embodiment.

FIG. 2 is similar to FIG. 1, but with a fixing component assembled in a main body.

FIG. 3 is a schematic view of a printed circuit board of related art.

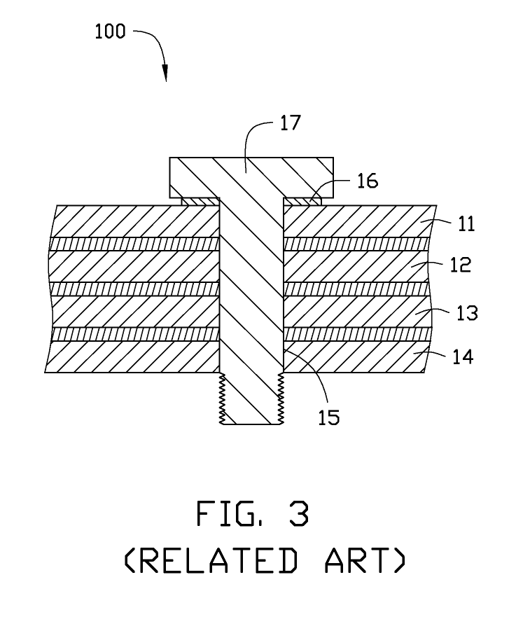

### DETAILED DESCRIPTION

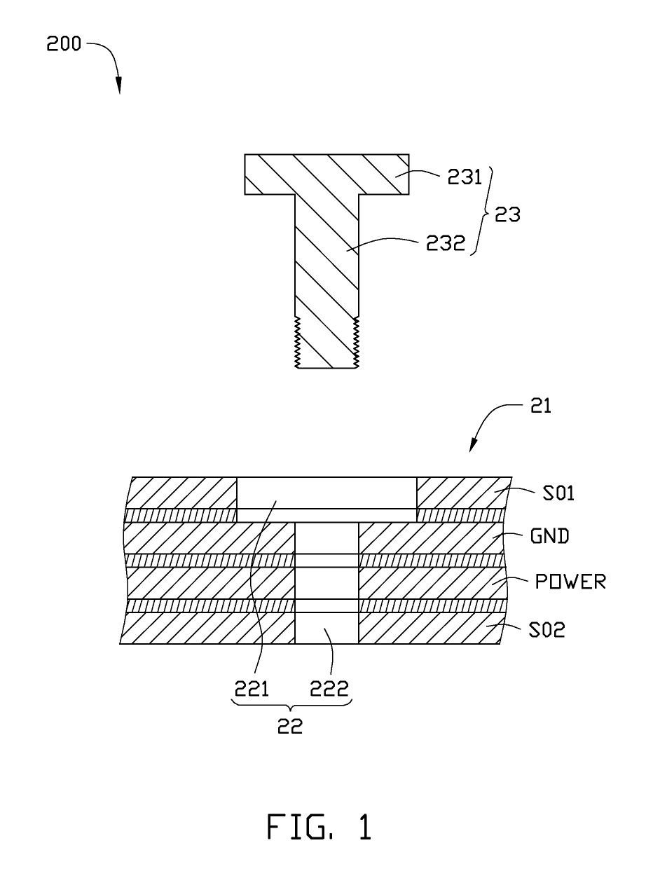

FIG. 1 is a schematic view of a printed circuit board (PCB) 200, according to an exemplary embodiment. The PCB 200 may be employed in an electronic device, such as a computer, a server, or a personal digital assistant, for example, and connected to a grounding point of the electronic device.

The PCB 200 includes a main body 21. In this embodiment, the main body 21 is a four-layer PCB, and includes a first signal layer S01, a grounding layer GND, a power layer POWER, and a second signal layer S02, arranged in that order. Dielectric materials (not labeled) are respectively sandwiched between adjacent the first signal layer S01, the grounding layer GND, the power layer POWER, and the second signal layer S02, for insulation purposes.

A through hole 22 is defined on the main body 21, and is configured for connecting to a grounding point of the electronic device, so that the PCB 200 is grounded. The through hole 22 includes a latching hole 221 and a connecting hole 222. The latching hole 221 is defined by and extends through a top layer (i.e., the first signal layer S01) of the PCB 200. The connecting hole 222 is defined by and extends from a bottom layer (i.e., the second signal layer S02) of the PCB 200 to the grounding layer GND, and communicates with the latching hole 221. In one embodiment, a diameter of the latching hole 221 is greater than a diameter of the connecting hole 222.

The PCB 200 further includes a fixing component 23. In this embodiment, the fixing component 23 is a bolt. The fixing component 23 includes a head portion 231 and a body portion 232 extending from the head portion 231. The head portion 231 can be received in the latching hole 221 and connects to the grounding layer GND by direct insulated surface contact. An outer screw thread (not labeled) is formed on an end of the body portion 232 spaced apart from the head portion 231. The body portion 232 can be received in the connecting hole 222 and connects to a grounding point of the electronic device through the outer screw thread. In this embodiment, the head portion 231 and the latching hole 221 have substantially the same shape and size, and the body portion 232 and the connecting hole 222 have substantially the same shape and size.

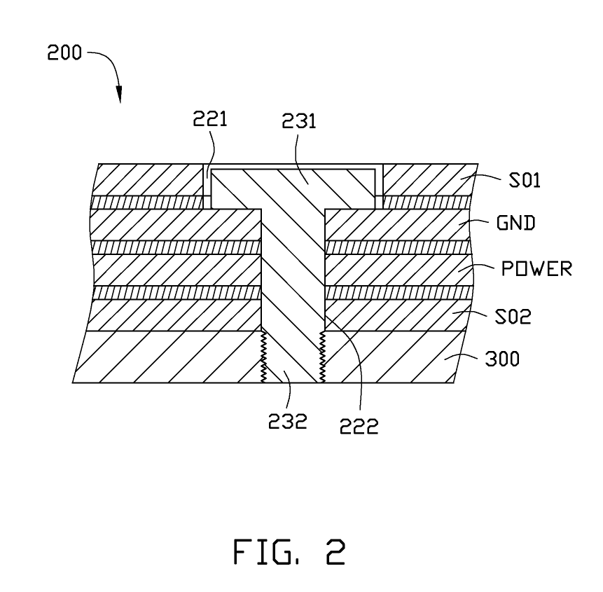

Referring to FIG. 2, in assembly of the PCB 200, firstly, the fixing component 23 is inserted through and engaged in the through hole 22. At this time, the head portion 231 of the fixing component 23 is received in the latching hole 221, and attached to the grounding layer GND. Furthermore, the body portion 232 of the fixing component 23 passes though the connecting hole 222, and by means of the outer screw thread engages with a grounding point of the electronic device, such as a housing 300 which is electronically connected to the grounding layer GND. Thus, due to a direct connection between the head portion 231 of the fixing component 23 and the grounding layer GND, interfering current of the PCB 200 can flow to the ground point via a path of the head portion 231 of the fixing component 23→the grounding layer GND→the ground point→ground.

In use, the PCB 200 does not need a dedicated conductive component on a surface of the main body 21 and the length of the fixing component 23 is also effectively reduced, thereby reducing a grounding resistance of the fixing component 23, and reducing a production cost of the PCB 200. Furthermore, due to the direct and full connection between the head portion 231 of the fixing component 23 and the grounding layer GND, the interfering current of the PCB 200 can flow to the grounding point without hindrance and thus be absolutely removed, thereby reducing any electromagnetic interference of the PCB 200.

In the present specification and claims, the word “a” or “an” preceding an element does not exclude the presence of a plurality of such elements. Further, the word “comprising” does not exclude the presence of elements or steps other than those listed.

It is to be also understood that even though numerous characteristics and advantages of exemplary embodiments have been set forth in the foregoing description, together with details of the structures and functions of the embodiments, the disclosure is illustrative only, and changes may be made in detail, especially in the matter of arrangement of parts within the principles of this disclosure to the full extent indicated by the broad general meaning of the terms in which the appended claims are expressed.

What is claimed is:

1. A printed circuit board (PCB), comprising:
a main body comprising a first signal layer, a grounding layer, a power layer, and a second signal layer, arranged in that order; and
a fixing component comprising a head portion and a body portion; wherein a through hole is defined on the main body, and comprises a latching hole and a connecting hole; the latching hole is defined by and extends through the first signal layer; the connecting hole is defined by and extends from the second signal layer to the grounding layer, and communicates with the latching hole; the head portion and the body portion of the fixing component are respectively received in the latching hole and the connecting hole.

2. The PCB of claim 1, wherein the head portion of the fixing component and the latching hole have substantially the same shape and size.

3. The PCB of claim 1, wherein the body portion of the fixing component and the connecting hole have substantially the same shape and size.

4. The PCB of claim 1, wherein a diameter of the latching hole is greater than a diameter of the connecting hole.

5. The PCB of claim 1, wherein an outer screw thread is formed on an end of the body portion spaced apart from the head portion, and the body portion by means of the outer screw thread engages with a grounding point which is electronically connected to the grounding layer.

6. The PCB of claim 5, wherein the PCB is received in an electronic device, and the body portion is connected to a housing of the electronic device through the outer screw thread.

7. The PCB of claim 5, wherein interfering current of the PCB flows to the ground point through the head portion of the fixing component and the grounding layer.

8. A PCB for connecting to a grounding point of an electronic device, comprising:
a fixing component; and
a main body comprising a first signal layer, a grounding layer, a power layer, and a second signal layer, arranged in that order; wherein a through hole is defined on the main body, and comprises a latching hole and a connecting hole; the latching hole is defined by and extends through the first signal layer; the connecting hole is defined by and extends from the second signal layer to the grounding layer, and communicates with the latching hole; the fixing component passes through the through hole, and thereby connects to the grounding point of the electronic device.

9. The PCB of claim 8, wherein a diameter of the latching hole is greater than a diameter of the connecting hole.

10. The PCB of claim 8, wherein the fixing component comprises a head portion received in the latching hole.

11. The PCB of claim 10, wherein interfering current of the PCB flows to the ground point through the head portion of the fixing component and the grounding layer.

12. The PCB of claim 10, wherein the fixing component comprises a body portion extending from the head portion and the body portion is received in the connecting hole.

13. The PCB of claim 12, wherein an outer screw thread is formed on an end of the body portion spaced apart from the head portion and the body portion is connected to the grounding point through the outer screw thread.

14. The PCB of claim 13, wherein the electronic device comprises a housing and the body portion is connected to the housing through the outer screw thread.
